(19) United States
(12) Patent Application Publication
(10) Pub. No.: US 2007/0075636 A1
(43) Pub. Date: Apr. 5, 2007

(54) Organic electroluminescent element

(75) Inventors: Manabu Tobise, Kanagawa (JP); Kazuhiro Hasegawa, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/529,538

(22) Filed: Sep. 29, 2006

(30) Foreign Application Priority Data
Sep. 30, 2005 (JP) 2005-288832

(51) Int. Cl. H01L 51/52; H01L 51/54

(52) U.S. Cl. 313/506; 428/690; 428/917; 313/504

(57) ABSTRACT

According to an aspect of the invention, there is provided an organic electroluminescent element including, between a pair of electrodes, a plurality of layers including at least one light-emitting layer, wherein at least one layer of the plurality of layers contains a main component and an accessory component (dopant), and a volume ratio of the main component to the accessory component varies in proportion to a distance from an electrode terminal.

### CROSS-REFERENCE TO RELATED APPLICATION

This application claims priority under 35 USC 119 from Japanese Patent Application No. 2005-288832, the disclosure of which is incorporated by reference herein.

### BACKGROUND OF THE INVENTION

1. Field of the Invention

The present invention relates to an organic electroluminescent element (hereinafter, referred to as an “organic EL element”, a “light-emitting element” or an “EL element” in some cases) that can convert electric energy into light to emit light.

2. Description of the Related Art

Today, research and development of various kinds of display elements are being actively carried out. Among these, organic electroluminescent (EL) elements, being able to obtain high brightness emission at low voltage, are attracting attention as promising display elements.

An organic electroluminescent element has a pair of electrodes that sandwiches a light-emitting layer or plural organic layers including a light-emitting layer. In the organic electroluminescent element, electrons injected from a cathode and holes injected from an anode recombine in a light-emitting layer, and generated excitons emit light, or excitons of other molecules, which are generated by energy transfer from the excitons, emit light.

In an organic electroluminescent element, as a transparent electrode, ITO (indium tin oxide) and ZnO (zinc oxide) are used. However, these transparent electrodes show high resistivity. Accordingly, as the distance from the terminal increases, the resistance increases and thus the amount of current to the organic layer decreases, resulting in decrease in brightness and unevenness in brightness.

As a method of overcoming unevenness in brightness, a surface light-emitting device has been disclosed, which has a transparent substrate, a surface light-emitting element, a connection terminal portion and a light-scattering means that is disposed so as to be denser as the distance from the connection terminal portion increases (see Japanese Patent Application Laid-Open (JP-A) No. 2005-142002).

However, in the surface light-emitting device, though an improvement is attempted by changing a light extraction effect, the improvement is insufficient.

Furthermore, it has been disclosed that, in an EL element, a light-emitting layer is made wider as the distance from the connection point of an electrode layer and a lead increases (see JP-A No. 2002-325162).

However, in order to obtain an appropriate amount of current in an organic layer at a position distant from the connection point, the voltage applied to the entirety becomes high. Furthermore, since the layer thickness is uneven and thus the interference effect varies at different positions, the chromaticity varies at different positions to cause unevenness.

### SUMMARY OF THE INVENTION

The present invention has been made in view of the above circumstances and provides an organic electroluminescent element.

According to an aspect of the invention, there is provided an organic electroluminescent element comprising, between a pair of electrodes, a plurality of layers including at least one light-emitting layer, wherein at least one layer of the plurality of layers contains a main component and an accessory component (dopant), and a volume ratio of the main component to the accessory component varies in proportion to a distance from an electrode terminal.

### BRIEF DESCRIPTION OF THE DRAWINGS

FIG. 1A is a schematic cross-sectional configuration diagram showing an example of an organic electroluminescent element (with terminals on one side) according to the invention.

FIG. 1B is a schematic cross-sectional configuration diagram showing another example of an organic electroluminescent element (with terminals on both sides) according to the invention.

FIG. 2 is a schematic cross-sectional configuration diagram showing still another example of an organic electroluminescent element (with terminals on one side and with a Li-doped Alq₃ layer) according to the invention.

FIG. 3A is a schematic diagram that shows a method of forming a light-emitting layer in the invention, wherein a concentration of a light-emitting material varies along a lower electrode.

FIG. 3B is a schematic diagram that shows another mode of a method of forming a light-emitting layer in the invention, wherein a concentration of a light-emitting material varies along a lower electrode.

### DETAILED DESCRIPTION OF THE INVENTION

In what follows, an organic electroluminescent element (hereinafter, in some cases, referred to as an “organic EL element”) according to the invention will be described in detail.

An organic electroluminescent element according to the invention includes, between a pair of electrodes, plural layers including at least one light-emitting layer, at least one layer of the plural layers containing a main component and an accessory component (dopant), with the volume ratio of the main component to the accessory component varying in proportion to the distance from an electrode terminal.

The organic electroluminescent element according to the invention, which is configured as mentioned above, can reduce unevenness in brightness without lowering the emission characteristics (external quantum efficiency).

Firstly, an organic electroluminescent element according to the invention will be described.

The organic electroluminescent element according to the invention includes, between a pair of electrodes, plural layers including at least one light-emitting layer, and at least one layer of the plural layers contains a main component and an accessory component (dopant).

The at least one layer of the plural layers, though not restricted to any particular one, is preferably a light-emitting layer from the viewpoint of easy control of the brightness.

When the at least one layer of the plural layers is a light-emitting layer, the main component is preferably a host material and the accessory component is preferably a light-emitting material.

Here, the main component means a component contained in the largest amount in the at least one layer of the plural layers.

In the invention, the volume ratio of the main component to the accessory component varies in proportion to the distance from the electrode terminal.

The electrode terminal means a connection portion between one electrode of the pair of electrodes and a lead that is used to apply an electric field to the light-emitting element. The connection portion may be a point, a line or a surface without restriction to any particular one.

As the one electrode of the pair of electrodes, generally, an electrode high in resistivity is preferably selected without restriction to any particular one.

The electrode terminal may be disposed at any place without any particular restriction.

Furthermore, the volume ratio of the main component to the accessory component (hereinafter, in some cases, simply referred to as a “quantity ratio”) varying in proportion to the distance from an electrode terminal means that a quantity ratio of the main component to the accessory component varies.

This means that, as the distance from an electrode terminal of an anode increases, the volume ratio varies so that one of the main component or the accessory component increases or decreases.

For instance, when the main component is a host material and the accessory component is a light-emitting material (dopant), as the distance from the electrode terminal connected to the anode becomes larger (more distant), the light-emitting material (dopant) is increased relative to the host material. In the light-emitting layer, by increasing the concentration of the light-emitting material that is an accessory component in the host material that is a main component, the probability of recombining in the light-emitting material becomes high, so that high external quantum efficiency is obtained. In this way, a constant brightness can be maintained, even if the voltage is lowered and the amount of current is decreased when the distance from the electrode terminal increases. Depending on the materials selected, in some cases, the dopant is relatively decreased.

A method of varying the quantity ratio of the main component to the accessory component is not restricted to any particular one. For example, when a co-deposition is carried out to form the layer, a crucible containing a material of the main component and a crucible containing a material of the accessory component may be located at positions opposed to each other along a length direction of the element.

The hole injection layer or hole transport layer of the EL element of the present invention can include a hole injection transport material as the main component, and an electron-accepting dopant as the accessory component. As the electron-accepting dopant to be introduced to the hole injection layer or hole transport layer, any of inorganic compounds and organic compounds can be used as long as it has an electron-accepting property and thus oxidizes an organic compound.

Examples of the inorganic compounds include metal halides such as ferric chloride, aluminum chloride, gallium chloride, indium chloride and antimony pentachloride, and metal oxides such as vanadium (V) oxide and molybdenum trioxide.

Examples of the organic compounds include compounds having a substituent such as nitro group, halogen, cyano group and trifluoromethyl group, quinone compounds, acid anhydrides, and fullerenes. In addition, compounds described in JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637 and 2005-209643, the disclosures of which are incorporated by reference herein, can be preferably used.

These electron-accepting dopants, which are accessory components, may be used alone or in combination of two or more kinds thereof The volume ratio of the main component to the accessory component in the layer, which varies according to the kinds of the materials, is preferably 100-x : x (%) wherein x varies in the range of 0<x≦20, more preferably 100-x: x (%) wherein x varies in the range of 0<x≦10, and particularly preferably 100-x: x (%) wherein x varies in the range of 0<x≦0.3.

By varying the concentration of the electron-accepting dopant that is an accessory component, the amount of current can be controlled. In this way, a constant amount of current can be maintained to maintain a constant brightness, even if the voltage is lowered when the distance from the electrode terminal increases.

Alternatively, the electron injection layer or electron transport layer of the organic EL element of the invention can include an electron injection transport material as the main component, and an electron-donating dopant as the accessory component. The electron-donating dopant, which is introduced to the electron injection layer or electron transport layer, may be any material as long as it has an electron donating property and thus reduces an organic compound. Preferable examples thereof include alkali metals such as Li, alkaline earth metals such as Mg, transition metals including rare earth metals, and reducing organic compounds. As the metals, metals having a work function of 4.2 eV or less can be preferably used. Examples thereof include Li, Na, K, Be, Mg, Ca, Sr, Ba, Y. Cs, La, Sm, Gd and Yb. Examples of the reducing organic compounds include nitrogen-containing compounds, sulfur-containing compounds and phosphorous-containing compounds.

Further, materials described in JP-A Nos. 6-212153, 2000-196140, 2003-68468, 2003-229278 and 2004-342614, the disclosures of which are incorporated by reference herein, can be used.

These electron-donating dopants may be used alone or in combination of two or more kinds thereof Although the amount of the electron-donating dopant to be used varies according to the kind of the material, the volume ratio of the main component to the accessory component in the layer is preferably 100-x : x (%) wherein x varies in the range of 0<x≦20, more preferably 100-x : x (%) wherein x varies in the range of 0<x≦5, and particularly preferably 100-x : x (%) wherein x varies in the range of 0<x≦0.2.

By varying the concentration of the electron-donating dopant that is an accessory component, the amount of current can be controlled. In this way, a constant amount of current can be maintained to maintain a constant brightness, even if the distance from the electrode terminal is increased and the voltage is lowered.

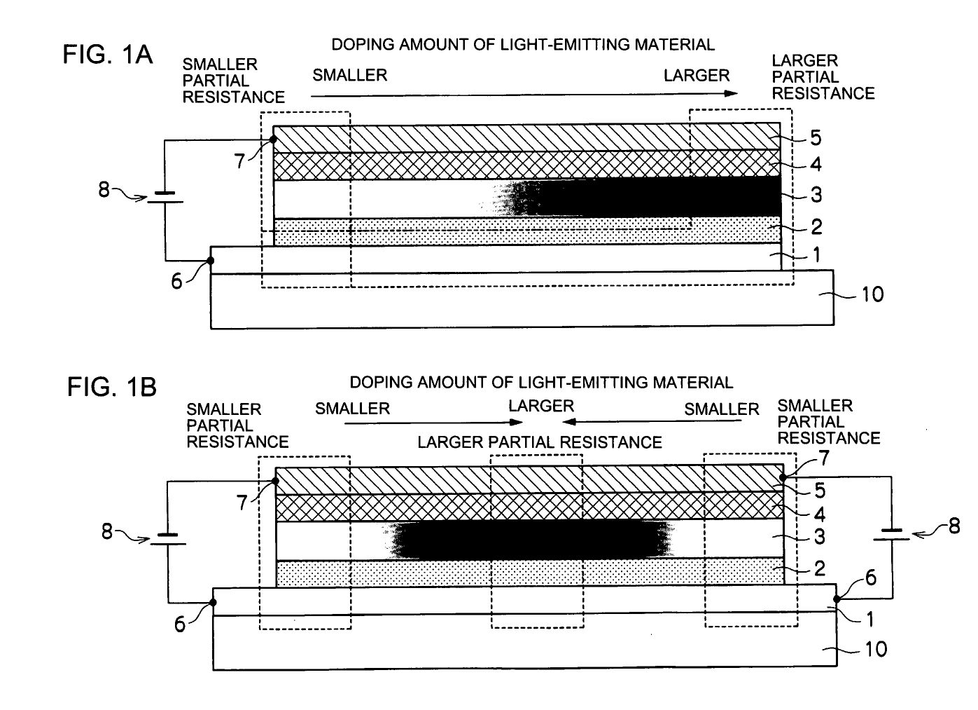

Next, a manufacturing method of an example of a light-emitting element according to the invention will be described with reference to FIGS. 1A, 2 and 3A and FIGS. 1B and 3B. However, the invention is not restricted to these.

FIG. 1A is a cross-sectional configuration diagram showing an example of an organic electroluminescent element (a case where electrode terminals are on one side) where the volume ratio of a main component and an accessory component in a light-emitting layer is varied.

FIG. 1A is an organic electroluminescent element having a bottom emission structure that uses a transparent electrode (ITO) as a lower electrode 1.

(1) First, a hole injection and transport layer 2 is formed on a substrate 10 on which the ITO transparent electrode 1 is formed, by heating and depositing a material (e.g. Phthalocyanine Copper (CuPC), N,N′-di-α-naphthyl-N,N′-diphenyl-benzidine (α-NPD)) described below. The ITO transparent electrode 1 is connected to a power supply through an electrode terminal 6.

(2) Next, thereon, using a host material that is a main component and a light-emitting material (e.g. 4,4′-N,N′-Bis(carbazol-9-yl)biphenyl (CBP) and Bis(3,5-difluoro-2-(2-pyridyl)phenyl)-(2-carboxypyridyl)iridium (III) (Firpic)) that is an accessory component (dopant), binary co-deposition is carried out so that the dopant increases as the distance from the electrode terminal becomes larger, whereby a light-emitting layer 3 is formed.

A specific method of the binary co-deposition will be described later.

(3) Subsequently, on the light-emitting layer 3, in an order of an electron transport layer and an electron injection layer 4, the respective layers are formed by depositing materials described below (for instance, Bis-(2-methyl-8-quinolinolate)-4-(phenylphenolato)aluminium (III) (BAlq), Tris(8-quinolinolate)aluminum (Alq₃) and LiF).

(4) Furthermore, an upper electrode layer (cathode, for instance, Al) 5 is formed on the electron transport layer and electron injection layer 4.

According to the above, a light-emitting element can be formed.

The upper electrode 5 is connected to a power supply 8 through an electrode terminal 7.

In FIG. 1A, a portion encircled by a dashed line on the side of the electrode terminals 6 and 7 is a region that is nearer to the electrode terminal 6 and thus shows smaller partial resistance. A portion encircled by a dashed line on the right side in the Figure is a portion that is more distant from the electrode terminal 6 and thus shows larger partial resistance due to the resistance of the lower electrode layer 1.

That is, in FIG. 1A, the resistance of the organic electroluminescent element is low in a portion closest to the electrode terminal 6, and becomes larger as the distance from the electrode terminal 6 increases in parallel with the lower electrode 1.

As mentioned above, the mass of the dopant (light-emitting material) in the light-emitting layer increases relative to the host material that is the main component as the distance from the electrode terminal becomes larger to increase the light amount per unit current, whereby the apparent light amount obtained from the anode side at a portion of the light-emitting element close to the electrode terminals 6 and 7 and the apparent light amount obtained from the anode side at a portion of the light-emitting element apart from the electrode terminals 6 and 7 can be made the same. Thus, there is no difference in the light amounts, whereby unevenness in the brightness can be eliminated.

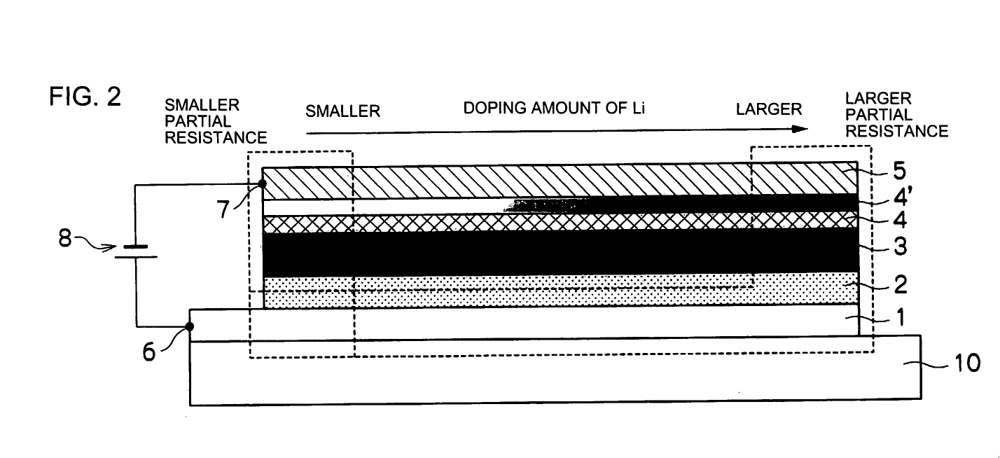

FIG. 2 is a cross-sectional configuration diagram showing an example of an organic electroluminescent element (a case where electrode terminals are on one side) where the volume ratio of an electron injection layer material that is a main component and Li that is an accessory component is varied.

FIG. 2 shows an organic electroluminescent element having a bottom emission structure where a transparent electrode (ITO) is used as a lower electrode 1.

(1) In the beginning, on a substrate 10 on which the ITO transparent electrode 1 is formed, a hole injection and transport layer 2 is formed by heating and depositing a material (e.g. CuPC/NPD) described below. The ITO transparent electrode is connected to a power supply through an electrode terminal 6.

(2) Furthermore, thereon, using a host material and a light-emitting material (e.g. CBP and Firpic), binary co-deposition is carried out to form a light-emitting layer 3.

(3) Subsequently, an electron transport layer (for instance, BAlq) 4 is deposited on the light-emitting layer 3.

(4) Furthermore, an Alq₃ layer 4′ is formed by carrying out binary co-deposition of an electron injection material (for instance, Alq₃) as a main component and Li as an accessory component so that the accessory component Li increases as the distance from the electrode terminal increases.

As to the binary co-deposition, a specific method will be described later.

(5) Subsequently, on the Alq₃ layer 4′, an upper electrode layer (cathode, for instance, Al) 5 is formed.

According to the above process, a light-emitting element can be formed.

The upper electrode 5 is connected, through an electrode terminal 7, to a power supply 8.

In FIG. 2, a portion encircled by a dashed line on the side of the electrode terminals 6 and 7 is a region that is nearer to the electrode terminal 6 and thus shows smaller partial resistance. A portion encircled by a dashed line on the right side in the Figure is a portion that is more distant from the electrode terminal 6 and thus shows larger partial resistance due to the resistance of the lower electrode layer 1.

That is, in FIG. 2, the resistance of the organic electroluminescent element is low in a portion closest to the electrode terminal 6, and becomes larger as the distance from the electrode terminal 6 becomes larger in parallel with the lower electrode 1.

When the above configuration is adopted, effects similar to FIG. 1A can be obtained.

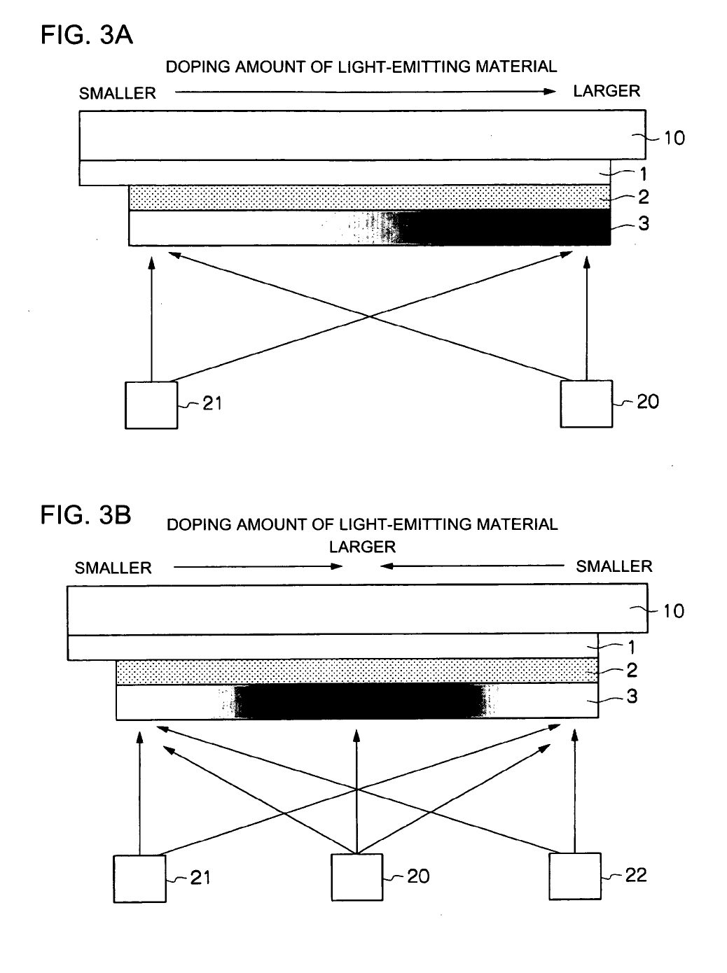

Next, the formation of a light-emitting layer or the like by the binary co-deposition will be described with reference to FIG. 3A.

FIG. 3A is a diagram showing a method of depositing to form a light-emitting layer of the FIG. 1A.

In the beginning, a crucible 20 containing a dopant that is one of components of the light-emitting layer 3 is placed at a crucible position (at a right edge in the Figure) to give the highest dopant concentration.

A crucible 21 containing a host material that is the other component is placed at a crucible position (at a left edge in the Figure) to give the lowest dopant concentration.

Subsequently, each of the crucibles is heated and controlled to a desired temperature thereof to deposit each of the materials.

Owing to the above operation, a light-emitting layer where a dopant concentration distribution is controlled can be obtained.

Next, with reference to FIG. 1B, an organic electroluminescent element having electrode terminals on both sides will be described.

FIG. 1B is a cross-sectional configuration diagram showing another example of an organic electroluminescent element (a case where electrode terminals are on both sides) where the volume ratio of a main component and an accessory component of a light-emitting layer is varied.

It shows that the partial resistance is highest at a center portion of the light-emitting layer.

FIG. 1B is an organic electroluminescent element having a bottom emission structure that uses a transparent electrode (ITO) as a lower electrode 1.

In the beginning, on a substrate 10 on which the ITO transparent electrode 1 is formed, a hole injection and transport layer 2 is formed by heating and depositing a material (for instance, CuPC.NPD) described below. The ITO transparent electrode is connected, through an electrode terminal 6, to a power supply.

Next, thereon, using a host material that is the main component and a light-emitting material (for instance, CBP and Firpic) that is the accessory component (dopant), ternary co-deposition is carried out so that the dopant increases as the distance from the electrode terminal 6 increases, whereby a light-emitting layer 3 is formed.

A specific method of the ternary co-deposition will be described later.

Subsequently, on the light-emitting layer 3, in an order of an electron transport layer and an electron injection layer 4, the respective layers are formed by depositing materials described below (for instance, BAlq, Alq₃ and LiF).

Furthermore, on the electron transport layer and electron injection layer 4, an upper electrode layer (cathode, for instance, Al) 5 is formed.

According to the above, a light-emitting element can be formed.

The upper electrode 5 is connected, through an electrode terminal 7, to a power supply 8.

In FIG. 1B, portions each encircled by a dashed line close to electrode terminals 6 and 7 on left edge and right edge sides show regions smaller in partial resistance, and a portion encircled by a dashed line at a center portion shows a region that is more distant from the electrode terminals 6 and thus affected by the resistance of the lower electrode layer 1 to thereby have larger partial resistance.

That is, in FIG. 1B, the resistance of the organic electroluminescent element is low in portions closest to the electrode terminals 6 and 7, and becomes larger as the distance from the electrode terminals 6 and 7 increases in parallel with the lower electrode 1.

When the above configuration is adopted, effects similar to FIG. 1A can be obtained.

The ternary co-deposition in the formation of the light-emitting layer will be described with reference to FIG. 3B.

FIG. 3B is a diagram showing a method of depositing to form a light-emitting layer of the FIG. 1B.

A crucible 20 containing a dopant that is one of components of the light-emitting layer 3 is placed at a crucible position (at a center in the Figure) to give the highest dopant concentration, and crucibles 21 and 22 each containing a host material that is another component are placed at crucible positions (at left and right edges in the Figure) to give the lowest dopant concentration.

Subsequently, each of the crucibles 20 through 22 is heated and controlled to a desired temperature thereof to deposit each of the materials, whereby a light-emitting layer that is controlled to a desired dopant concentration distribution can be obtained.

Next, a configuration of an organic electroluminescent element according to the invention will be described.

The organic electroluminescent element according to the invention has a pair of a cathode and an anode, and plural layers that include at least a light-emitting layer and are between the electrodes.

The cathode and anode are preferably formed on a substrate.

Furthermore, between the light-emitting layer and the anode, and between the light-emitting layer and the cathode, other layers may be provided.

From the nature of the light-emitting element, at least one of the anode and the cathode is, in an ordinary case, transparent.

As a mode of layering an organic electroluminescent element in the invention, a mode where a hole transport layer, a light-emitting layer and an electron transport layer are layered in this order from the anode side is preferable.

Furthermore, between the hole transport layer and the light-emitting layer, and between the electron transport layer and the light-emitting layer, a charge blocking layer may be provided.

As mentioned above, in the invention, following layer configurations can be exemplified.

(1) A cathode/plural layers/an anode (bottom emission structure), and

(2) A cathode/plural layers/an anode (top emission structure).

Furthermore, the configurations (1) and (2) may have electrode terminals on one side or both sides

Furthermore, the cathode and the anode are preferably formed on a substrate.

Still furthermore, between the light-emitting layer and the anode, and between the light-emitting layer and the cathode, other layers may be provided.

From the nature of the light-emitting element, at least one of the anode and the cathode is, in an ordinary case, transparent.

As a mode of layering the organic electroluminescent element in the invention, a mode where a hole transport layer, a light-emitting layer and an electron transport layer are layered in this order from the anode side is preferable.

Furthermore, between the hole transport layer and the light-emitting layer, and between the electron transport layer and the light-emitting layer, a charge blocking layer may be provided.

Next, elements constituting the invention will be described in detail.

[Substrate]

As a substrate that can be applied to the invention, in general, a glass substrate, a ceramic substrate, a metal substrate or a resin substrate containing an organic polymer can be exemplified. When a reflective layer is formed outside of an electrode relative to a light-emitting layer, the reflective layer may be a layer that works as a substrate.

[Electrode]

In a mode where a light reflection function is provided to any of the electrodes, at least one of the anode and the cathode is preferably a light-transmitting (transparent or translucent) material from the nature of the light-emitting element. In an ordinary case, the anode is transparent.

Furthermore, when a reflective layer is disposed as a layer separate from the electrodes, both of the pair of electrodes are preferably a light-transmitting material and more preferably a transparent material.

Examples of materials of the light-transmitting electrode include ITO (indium-tin oxide), ZnO, Al, composite oxides described in JP-A No. 10-190028 (the disclosure of which is incorporated by reference herein), GaN materials described in JP-A No. 6-150723 (the disclosure of which is incorporated by reference herein), materials described in JP-A Nos. 8-262225, 8-264022 and 8-264023 (the disclosures of which are incorporated by reference herein), which contain Zn₂In₂O₅, (Zn, Cd, Mg)O—(B, Al, Ga, In, Y)₂O₃—(Si, Ge, Sn, Pb, Ti, Zr)O₂ or (Zn, Cd, Mg)O—(B, Al, Ba, In, Y)₂O₃—(Si, Sn, Pb)O or MgO—In₂O₃ as a main component, and SnO₂ materials. Alternatively, as a light-transmitting electrode, a super-thin film of a metal such as Al, Cu, Ag and Au can be used.

[Plural Layers]

Plural layers in the invention includes at least one light-emitting layer.

As a mode of layering plural layers in the invention, a mode where a hole transport layer, a light-emitting layer and an electron transport layer are layered in this order from the anode side is preferable.

Furthermore, between the hole transport layer and the light-emitting layer, or between the light-emitting layer and the electron transport layer, a charge blocking layer (electrons, holes, excitons) may be disposed. Between the anode and the hole transport layer, a hole injection layer may be disposed, and, between the cathode and the electron transport layer, an electron injection layer may be disposed.

Still furthermore, the light-emitting layer may be disposed as a single layer or may be divided into a first light-emitting layer, a second light-emitting layer, a third light-emitting layer and so on. Furthermore, each of the layers may be divided into plural secondary layers.

The light-emitting layer is a layer that has a function of, at the time of voltage application, receiving holes from the anode, hole injection layer or hole transport layer and electrons from the cathode, electron injection layer or electron transport layer and providing a field where the holes and electrons recombine to emit light.

The light-emitting layer in the invention may consist of only a light-emitting material or may be a layer in which a host material and a light-emitting material are mixed together.

When at least one layer of the plural layers is a light-emitting layer and contains a main component and an accessory component, it is preferable that the main component is a host material and the accessory component is a light-emitting material.

In the at least one layer of the plural layers, the volume ratio of the main component to the accessory component in the layer is preferably 100-x : x (%) wherein x varies in the range of 0<x≦20, more preferably 100-x: x (%) wherein x varies in the range of 2<x≦18, and particularly preferably 100-x : x (%) wherein x varies in the range of 5<x≦14. When the volume ratio of the main component to the accessory component is 100-x : x (%) wherein x varies in the range of 0<x≦20, the luminous efficiency can be optimized.

The light-emitting material may be a fluorescent material or a phosphorescent material, and may be one kind or two kinds or more. The host material is preferably a charge transport material. The host material may be one kind or two kinds or more and, for instance, a configuration where an electron transporting host material and a hole transporting host material are mixed can be exemplified. Furthermore, in the light-emitting layer, a material that neither has a charge transportability nor emits light may be contained.

Furthermore, the light-emitting layer may be a single layer or two or more layers and the respective layers may emit light in different emission colors.

A thickness of the light-emitting layer is, from viewpoints of unevenness in brightness, driving voltage and brightness, preferably in the range of 0.03 to 0.5 μm and more preferably in the range of 0.06 to 0.4 μm. When the thickness of the light-emitting layer is thin, the light-emitting layer can be operated at high brightness and low voltage. However, since the element resistance becomes small, the brightness may be readily affected by voltage lowering in some cases, resulting in increase in unevenness in brightness. On the other hand, when the thickness of the light-emitting layer is thick, the driving voltage becomes higher, the luminous efficiency is lowered, and thereby applications may be restricted.

Furthermore, when the light-emitting layer has a multi-layered structure, each thickness of the layers constituting the multi-layered structure is not particularly restricted. However, a total thickness of the respective layers is preferably in the above range.

Examples of the fluorescent materials that can be used in the invention, without restriction to any particular one, can be appropriately selected from known fluorescent materials. For instance, materials that are described in [0027] of JP-A No. 2004-146067 and [0057] of JP-A-2004-103577 (the disclosures of which are incorporated by reference herein) can be exemplified without restricting the invention thereto.

Furthermore, the phosphorescent materials and the host materials that can be used in the invention, without restriction to any particular one, can be appropriately selected from known materials. For instance, as the host materials, CBP and 1,3-Bis(carbazol-9-yl)benzene (mCP), and, as the light-emitting materials, Firpic, Tris(2-phenylpyridine)iridium(III) (Ir(ppy)₃), and ortho-metallized iridium complexes described in [0051] to [0057] of JP-A No. 2004-221068 (the disclosure of which is incorporated by reference herein) can be exemplified. However, the invention is not restricted thereto.

In the organic electroluminescent element according to the invention, as other elements such as the respective plural layers and other layers, for instance, ones described in [0013] to [0082] of JP-A No. 2004-221068, [0017] to [0091] of JP-A No. 2004-214178, [0024] to [0035] of JP-A No. 2004-146067, [0017] to [0068] of JP-A No. 2004-103577, [0014] to [0062] of JP-A No. 2003-323987, [0015] to [0077] of JP-A No. 2002-305083, [0008] to [0028] of JP-A No. 2001-172284, [0013] to [0075] of JP-A-2000-186094 and [0016] to [0118] of JP-T-2003-515897 (the disclosures of which are incorporated by reference herein) can be applied in the invention. However, the invention is not restricted thereto.

The organic EL element of the present invention can have a configuration in which a charge-generating layer is provided between plural light-emitting layers for improving luminous efficiency. The charge-generating layer have a function of generating a charge (hole or electron) when applying a voltage as well as a function of injecting the generated charge into a layer that is adjacent to the charge-generating layer.

The material for forming the charge-generating layer may be any material as long as it has the-above mentioned functions. The charge-generating layer may be formed of a single compound or plural compounds.

Specifically, the material may be a conductive material, a semiconductive material such as a doped organic layer, or an insulating material. Examples thereof include materials described in JP-A Nos. 11-329748, 2003-272860 and 2004-39617, the disclosures of which are incorporated by reference herein.

More specifically, examples include transparent conductive materials such as ITO and IZO (Indium Zinc Oxide), fullerenes such as C60, conductive organic materials such as oligothiophenes, conductive organic materials such as metallophthalocyanines, metal-free phthalocyanines, metalloporphyrins and metal-free porphyrins, metal materials such as Ca, Ag, Al, Mg:Ag alloys, Al:Li alloys and Mg:Li alloys, hole conductive materials, electron conductive materials, and mixtures thereof.

Examples of the hole conductive materials include materials obtainable by doping a hole transport organic material such as 4,4′,4″-Tris(2-naphthylphenylamino)triphenylamine (2-TNATA) and NPD with an oxidant having an electron accepting property such as 2,3,5,6-tetrafluoro-7,7,8,8-tetracyano-p-quinodimethane (F4-TCNQ), 7,7,8,8-tetracyano-p-quinodimethane (TCNQ) and FeCl₃, P-type conductive polymers and P-type semiconductors. Examples of the electron conductive materials include materials obtainable by doping an electron transport organic material with a metal or metal compound having a work function of less than 4.0 eV, N-type conductive polymers and N-type semiconductors. Examples of the N-type semiconductors include N-type Si, N-type CdS and N-type ZnS. Examples of the P-type semiconductors include P-type Si, P-type CdTe and P-type CuO.

Further, insulating materials such as V₂O₅ can be used for the charge-generating layer.

The charge-generating layer may be a single layer or laminated plural layers. Examples of the structure having laminated plural layers include a structure in which a conductive material such as a transparent conductive material and metal material, and a hole conductive material or electron conductive material are laminated, and a structure in which the hole conductive material and electron conductive material are laminated.

In general, it is preferable that the thickness and material of the charge-generating layer is selected so as to have a visible light transmittance of 50% or more. The thickness is not particularly limited, but preferably from 0.5 to 200 nm, more preferably from 1 to 100 nm, further preferably from 3 to 50 nm, and particularly preferably from 5 to 30 nm.

The method of forming the charge-generating layer is not particularly limited, and the method of forming organic compound layers as described above can be used.

The charge-generating layer is formed between the plural light-emitting layers, and each of the anode side and the cathode side of the charge-generating layer may contain a material having a function of injecting a charge into an adjacent layer. In order to improve the electron injecting property to the adjacent layer at the anode side, an electron injecting compound such as BaO, SrO, Li₂O, LiCl, LiF, MgF₂, MgO and CaF₂ may be layered on the charge-generating layer at the anode side.

Alternatively, the material of the charge-generating layer can be selected based on the descriptions of JP-A No. 2003-45676 and U.S. Pat. Nos. 6,337,492, 6,107,734 and 6,872,472, the disclosures of which are incorporated by reference herein.

As a driving method of the organic electroluminescent element of the invention, the driving methods described in the respective publications of JP-A Nos. 2-148687, 6-301355, 5-29080, 7-134558, 8-234685 and 8-241047 and specifications of Japanese Patent No. 2784615 and U.S. Pat. Nos. 5,828,429 and 6,023,308 (the disclosures of which are incorporated by reference herein) can be applied.

In general, when the aspect ratio (width and length of an element) of an organic electroluminescent element is a value exceeding 1, unevenness in brightness is caused, and the more the value increases, the more remarkable the unevenness in brightness tends to be.

Even when the aspect ratio is a value exceeding 1, a mode of the organic electroluminescent element of the invention prevents occurrence of the unevenness in brightness.

In particular, the present invention is effective for a line light source having a shape such that when the width is 1, the length is 100 or more. This is thought to be because, in such a line light source, the width of the electrode is short and thus the resistance value per unit length is high, whereby the voltage varies at different positions, often resulting in unevenness in brightness.

Therefore, the aspect ratio of the organic electroluminescent element of the invention is more preferably from 100 to 100000, further preferably from 1000 to 100000, particularly preferably from 2000 to 100000, and most preferably from 5000 to 100000.

The driving durability of the organic electroluminescent element of the invention can be measured as a half-life of the brightness at a particular brightness (half-life of durability). Using, for instance, a Source Measure Unit 2400 (trade name, manufactured by Keithley Co., Ltd.), a direct current voltage is applied to an organic EL element to emit light, and a continuous driving test is carried out at an initial brightness of 500 cd/m². In this test, the time when the brightness becomes 250 cd/m² is a half-life of the durability T (½). The half-life is compared with that of a previous light-emitting layer. In the invention, this numerical value is used.

As an important characteristic value of the organic electroluminescent element, there is an external quantum efficiency. The external quantum efficiency can be calculated from [external quantum efficiency φ=number of photons emitted from an element/number of electrons injected into the element] and the larger the value, the more advantageous the element is from a viewpoint of electric power consumption.

Furthermore, the external quantum efficiency of an organic electroluminescent element is determined by [external quantum efficiency φ=internal quantum efficiency×light extraction efficiency]. In an organic EL element that utilizes fluorescent emission from an organic compound, since a limit value of the internal quantum efficiency is 25% and the light extraction efficiency is about 20%, a limit value of the external quantum efficiency is considered about 5%.

In the invention, by use of a Source Measure Unit 2400 (trade name, manufactured by Keithley Co., Ltd.), a direct current constant voltage is applied to an EL element to emit light. The brightness, emission peak wavelength and waveform of an emission spectrum thereof were measured using a spectral radiometer SR-3 (trade name, manufactured by Topcon Corp.), whereby the external quantum efficiencies at 500 cd/m² and 50000 cd/m² can be calculated. In the invention, these values are used.

Furthermore, the external quantum efficiency of a light-emitting element can be obtained by measuring the emission brightness, emission spectrum and current density, followed by calculating from the results and the relative spectral sensitivity curve. That is, using a current density value, the number of inputted electrons can be calculated. Then, by an integral calculation using the emission spectrum and the relative spectral sensitivity curve (spectrum), the number of photons generated can be calculated from the emission brightness. Using these, the external quantum efficiency (%) can be calculated from [(the number of generated photons/the number of electrons inputted in the element)×100].

The internal quantum efficiency of the organic electroluminescent element according to the invention can be calculated from the internal quantum efficiency=the external quantum efficiency/light extraction efficiency. The light extraction efficiency of an ordinary organic EL element is about 20%. However, in the organic electroluminescent element according to the invention, by adjusting a shape of the substrate, a shape of the electrode, a thickness of the organic layer, a thickness of an inorganic layer, the refractive index of the organic layer and the refractive index of the inorganic layer, the light extraction efficiency can be made 20% or more.

The organic electroluminescent element according to the invention, though not particularly restricted in applications, can be preferably used in the fields of display elements, displays, backlights, electrophotography, illuminating light sources, recording light sources, exposing light sources, reading light sources, signs, billboards, interiors and optical communication.

### EXAMPLES

In what follows, the invention will be specifically described with reference to examples. However, the invention is not restricted thereto.

### Example 1

On a 0.5 mm thick and 2.5 cm square glass substrate, by means of DC magnetron sputtering (conditions: substrate temperature of 100° C. and oxygen pressure of 1×10⁻³ Pa) with an ITO target in which the content of In₂O₃ is 95 mass percent, an ITO thin film (thickness: 0.2 μm) as a transparent anode was formed. The surface resistance of the ITO thin film was 10 Ω/□.

Next, the substrate on which the transparent anode was formed was put in a cleansing vessel to wash with IPA, and subjected to a UV-ozone treatment for 30 min. On the transparent anode, cupper phthalocyanine (CuPC) was deposited by means of a vacuum deposition method at a speed of 0.1 nm/sec, whereby a 10 nm thick hole injection layer was formed.

Thereon, α-NPD ((N,N′-di-α-naphthyl-N,N′-diphenyl)-benzidine) was deposited by means of a vacuum deposition method at a speed of 0.3 nm/sec, whereby a 30 nm thick hole transport layer was formed.

Further thereon, CBP as a host material in a light-emitting layer and Firpic as a phosphorescent material in the light-emitting layer were co-deposited by means of a vacuum deposition method at a volume ratio (volume rate) of CBP 95%: Firpic 5% at the end portion that was nearest to the ITO electrode terminal and at a volume ratio (volume rate) of CBP 90%: Firpic 10% at the end portion that was farthest from the ITO electrode terminal so as to be constant in emission light amount, whereby a light-emitting layer having a thickness of 30 nm was obtained.

<Co-Deposition Method>

Crucible positions and deposition rates are controlled so that CBP and Firpic, respectively, are deposited by means of a vacuum deposition method at 0.3 nm/sec and 0.016 nm/sec at the end portion that is nearest to the ITO electrode terminal and at 0.284 nm/sec and 0.032 nm/sec at the end portion that is farthest from the ITO electrode terminal, whereby a co-deposition film having a uniform thickness of 30 nm and gradation introduced therein can be obtained.

On the light-emitting layer, as a hole-blocking layer (electron transport layer), BAlq was deposited by means of a vacuum deposition method at a speed of 0.5 nm/sec to be 10 nm, further thereon, as an electron transport material, Alq₃ was deposited by means of a vacuum deposition method at a speed of 0.2 nm/sec, whereby a 40 nm thick electron injection layer was formed.

Further on the layer, a patterned mask (a mask for forming an emission area of 2 mm×2 mm) was disposed, and lithium fluoride was deposited by 1 nm by means of a vacuum deposition method.

Still further, thereon, aluminum was deposited by means of a vacuum deposition method, whereby a 0.1 μm thick cathode was formed.

The obtained light-emitting layered product was put in a glove box replaced with argon gas, followed by sealing with a stainless sealing canister with a drying agent and a UV-curable adhesive (trade name: XNR5516HV, manufactured by Nagase Chiba Corp.), whereby a light-emitting element according to the invention was obtained.

Operations from the deposition of copper phthalocyanine to the sealing were carried out under vacuum or nitrogen atmosphere without exposing the element to air. 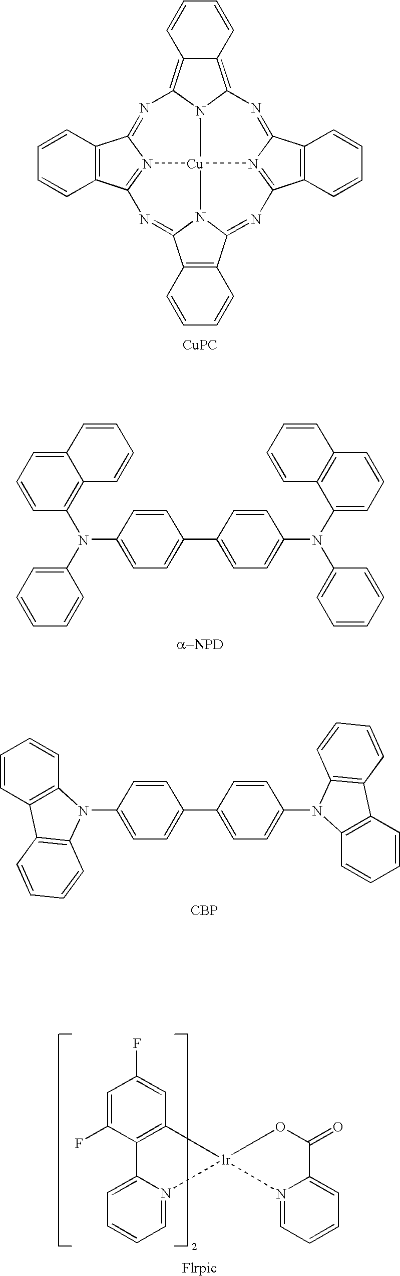 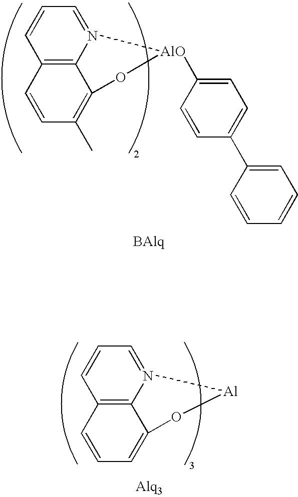
[Evaluation]

With the light-emitting element obtained in the above, unevenness in brightness and luminous efficiency were measured according to methods shown below. Results are shown in Table 1 below.

(1) Unevenness in Brightness

While flowing a constant current to the light-emitting element, the light-emitting element was scanned from the end portion at the side of the ITO electrode terminal to the end portion at the opposite side using a spectral radiometer SR-3 (trade name, manufactured by Topcon Corporation), whereby unevenness in brightness was measured and evaluated.

(2) Luminous Efficiency

The amount of current flowed to the light-emitting element was converted into a current density and, based on the amount of light measured by use of a spectral radiometer SR-3 (trade name, manufactured by Topcon Corporation), luminous efficiency was determined.

### Example 2

An organic electroluminescent element according to the invention was prepared in the same manner as in example 1 except for the following.

In the formation of the light-emitting layer according to example 1, in place of co-depositing CBP and Firpic at a volume ratio of CBP 95%: Firpic 5% at the end portion that was nearest to the ITO electrode terminal and at a volume ratio (volume rate) of CBP 90%: Firpic 10% at the end portion that was farthest from the ITO electrode terminal so as to be constant in emission light amount, a co-deposition of CBP and Firpic was carried out at a volume rate of 95: 5 by means of a vacuum deposition method, and furthermore, in the formation of Alq₃ layer in example 1, Alq₃ (main component) and Li (accessory component) were deposited by controlling the deposition speeds by means of a binary co-deposition method at a ratio of Alq₃ (main component) 99.9 (%): Li (accessory component) 0.1 (%) (the smallest Li doping amount) at the end portion that was nearest to the ITO electrode terminal and at a ratio of Alq₃ (main component) 98.5 (%): Li (accessory component) 1.5 (%) at the end portion that was farthest from the ITO electrode terminal so as to be constant in light amount even in a portion apart from the end portion that was nearest to the ITO electrode terminal.

The obtained organic electroluminescent element was evaluated in the same manner as in example 1, and results are shown in Table 1.

### Example 3

An organic electroluminescent element according to the invention was prepared in the same manner as in example 1 except for the following.

In the formation of the light-emitting layer according to example 1, in place of co-depositing CBP and Firpic at a volume rate of CBP 95%: Firpic 5% at the end portion that was nearest to the ITO electrode terminal and at a volume ratio (volume rate) of CBP 90%: Firpic 10% at the end portion that was farthest from the ITO electrode terminal so as to be constant in emission light amount, a co-deposition of CBP and Firpic was carried out at a volume rate of 95: 5 by means of a vacuum deposition method, and furthermore, in the formation of BAlq layer in example 1, BAlq (main component) and Li (accessory component) were deposited by controlling the deposition speeds by means of a binary co-deposition method at a ratio of BAlq (main component) 99.7 (%): Li (accessory component) 0.3 (%) (the smallest Li doping amount) at the end portion that was nearest to the ITO electrode terminal and at a ratio of BAlq (main component) 98.8 (%): Li (accessory component) 1.2 (%) at the end portion that was farthest from the ITO electrode terminal so as to be constant in light amount even in a portion apart from the end portion that was nearest to the ITO electrode terminal.

The obtained organic electroluminescent element was evaluated in the same manner as in example 1, and results are shown in Table 1.

### Example 4

An organic electroluminescent element according to the invention was prepared in the same manner as in example 1 except for the following.

In the formation of the light-emitting layer according to example 1, in place of co-depositing CBP and Firpic at a volume rate of CBP 95%: Firpic 5% at the end portion that was nearest to the ITO electrode terminal and at a volume ratio (volume rate) of CBP 90%: Firpic 10% at the end portion that was farthest from the ITO electrode terminal so as to be constant in emission light amount, a co-deposition of CBP and Firpic was carried out by a vacuum deposition method at a volume rate of 95:5, and furthermore, in the formation of α-NPD layer in example 1, α-NPD (main component) and 2,3,5,6-tetrafluoro-7,7,8,8-tetracyano-p-quinodimethane (F4-TCNQ) (accessory component) were deposited by controlling the deposition speeds by means of a binary co-deposition method at a ratio of α-NPD (main component) 99.9 (%): F4-TCNQ (accessory component) 0.1 (%) (the smallest F4-TCNQ doping amount) at the end portion that was nearest to the ITO electrode terminal and at a ratio of α-NPD (main component) 99.7 (%): F4-TCNQ (accessory component) 0.3 (%) at the end portion that was farthest from the ITO electrode terminal so as to be constant in light amount even in a portion apart from the end portion that was nearest to the ITO electrode terminal.

The obtained organic electroluminescent element was evaluated in the same manner as in example 1, and results are shown in Table 1.

### Comparative Example 1

In the formation of the light-emitting layer of example 1, the co-deposition of CBP and Firpic was changed to a co-deposition by means of a vacuum deposition method at a volume ratio (volume rate) of 95:5, and other layers were formed in the same manner as in example 1, whereby an organic electroluminescent element for comparison was obtained.

The obtained organic electroluminescent element was evaluated in the same manner as in example 1, and results are shown in Table 1.

TABLE 1

| | Main | Accessory | | | |
|---|---|---|---|---|---|
| | Component | Component | | | |
| | (layer containing | (layer containing the | Unevenness | Luminous | |
| | the component) | component) | in brightness | efficiency | Aspect ratio |
| Example 1 | CBP | Firpic | 0.13% | 5.12% | 16000 |
| | (light-emitting | (light-emitting layer) | | | |
| | layer) | | | | |
| Example 2 | Alq₃ | Li | 0.11% | 5.50% | 16000 |
| | (Alq₃ layer) | (Alq₃ layer) | | | |
| Example 3 | BAlq | Li | 0.11% | 6.10% | 16000 |
| | (BAlq layer) | (BAlq layer) | | | |
| Example 4 | NPD | F4-TCNQ | 0.12% | 6.20% | 16000 |
| | (NPD layer) | (NPD layer) | | | |
| Comparative | CBP | Firpic | 2.50% | 5.05% | 16000 |
| Example 1 | (light-emitting | (light-emitting layer) | | | |
| | layer) | | | | |

As clear from the Table 1, unevenness in brightness could be decreased without lowering the luminous efficiency.

The present invention provides at least the following embodiments 1 to 17.

1. An organic electroluminescent element comprising, between a pair of electrodes, a plurality of layers including at least one light-emitting layer, wherein at least one layer of the plurality of layers contains a main component and an accessory component (dopant), and a volume ratio of the main component to the accessory component varies in proportion to a distance from an electrode terminal.

2. The organic electroluminescent element of embodiment 1, wherein the at least one layer of the plurality of layers is a light emitting layer.

3. The organic electroluminescent element of embodiment 2, wherein the main component is a host material and the accessory component is a light-emitting material.

4. The organic electroluminescent element of embodiment 3, wherein the host material is 4,4′-N,N′-Bis(carbazol-9-yl)biphenyl (CBP) and the light emitting material is Bis(3,5-difluoro-2-(2-pyridyl)phenyl)-(2-carboxypyridyl) iridium (III) (Firpic).

5. The organic electroluminescent element of embodiment 1, wherein the at least one layer of the plurality of layers is a hole transport layer.

6. The organic electroluminescent element of embodiment 5, wherein the main component is N,N′-di-α-naphthyl-N,N′-diphenyl-benzidine (α-NPD) and the accessory component is 2,3,5,6-tetrafluoro-7,7,8,8-tetracyano-p-quinodimethane (F4-TCNQ).

7. The organic electroluminescent element of embodiment 1, wherein the at least one layer of the plurality of layers is a hole injection layer.

8. The organic electroluminescent element of embodiment 1, wherein the at least one layer of the plurality of layers is an electron transport layer.

9. The organic electroluminescent element of embodiment 8, wherein the main component is Bis-(2-methyl-8-quinolinolate)-4-(phenylphenolato)aluminium (BAlq) and the accessory component is Li.

10. The organic electroluminescent element of embodiment 1, wherein the at least one layer of the plurality of layers is an electron injection layer.

11. The organic electroluminescent element of embodiment 10, wherein the main component is Tris(8-quinolinolate)aluminum (Alq₃) and the accessory component is Li.

12. The organic electroluminescent element of embodiment 1, wherein the volume ratio of the main component to the accessory component in the at least one layer of the plurality of layers is 100-x: x (%) wherein x varies in the range of 0<x≦20.

13. The organic electroluminescent element of embodiment 1, wherein the aspect ratio of the organic electroluminescent element exceeds 1.

14. The organic electroluminescent element of embodiment 13, wherein the aspect ratio is in the range of 100 to 100000.

15. The organic electroluminescent element of embodiment 1, wherein at least one of the electrodes is a light-transmitting electrode.

16. The organic electroluminescent element of embodiment 1, wherein at least one of the electrodes is formed on a substrate.

17. The organic electroluminescent element of embodiment 1, wherein the thickness of the light-emitting layer is in the range of 0.03 to 0.5 μm.

Therefore, according to the invention, without lowering the luminous efficiency, an organic electroluminescent element wherein unevenness in brightness is reduced can be provided.

What is claimed is:

1. An organic electroluminescent element comprising, between a pair of electrodes, a plurality of layers including at least one light-emitting layer, wherein at least one layer of the plurality of layers contains a main component and an accessory component (dopant), and a volume ratio of the main component to the accessory component varies in proportion to a distance from an electrode terminal.

2. The organic electroluminescent element of claim 1, wherein the at least one layer of the plurality of layers is a light emitting layer.

3. The organic electroluminescent element of claim 2, wherein the main component is a host material and the accessory component is a light-emitting material.

4. The organic electroluminescent element of claim 3, wherein the host material is 4,4′-N,N′-Bis(carbazol-9-yl)biphenyl (CBP) and the light emitting material is Bis(3,5-difluoro-2-(2-pyridyl)phenyl)-(2-carboxypyridyl)iridium (III) (Firpic).

5. The organic electroluminescent element of claim 1, wherein the at least one layer of the plurality of layers is a hole transport layer.

6. The organic electroluminescent element of claim 5, wherein the main component is N,N′-di-α-naphthyl-N,N′-diphenyl-benzidine (α-NPD) and the accessory component is 2,3,5,6-tetrafluoro-7,7,8,8-tetracyano-p-quinodimethane (F4-TCNQ).

7. The organic electroluminescent element of claim 1, wherein the at least one layer of the plurality of layers is a hole injection layer.

8. The organic electroluminescent element of claim 1, wherein the at least one layer of the plurality of layers is an electron transport layer.

9. The organic electroluminescent element of claim 8, wherein the main component is Bis-(2-methyl-8-quinolinolate)-4-(phenylphenolato)aluminium (BAlq) and the accessory component is Li.

10. The organic electroluminescent element of claim 1, wherein the at least one layer of the plurality of layers is an electron injection layer.

11. The organic electroluminescent element of claim 10, wherein the main component is Tris(8-quinolinolate)aluminum (Alq₃) and the accessory component is Li.

12. The organic electroluminescent element of claim 1, wherein the volume ratio of the main component to the accessory component in the at least one layer of the plurality of layers is 100-x : x (%) wherein x varies in the range of 0<x≦20.

13. The organic electroluminescent element of claim 1, wherein the aspect ratio of the organic electroluminescent element exceeds 1.

14. The organic electroluminescent element of claim 13, wherein the aspect ratio is in the range of 100 to 100000.

15. The organic electroluminescent element of claim 1, wherein at least one of the electrodes is a light-transmitting electrode.

16. The organic electroluminescent element of claim 1, wherein at least one of the electrodes is formed on a substrate.

17. The organic electroluminescent element of claim 1, wherein the thickness of the light-emitting layer is in the range of 0.03 to 0.5 μm.
